(19) United States
(12) Patent Application Publication
(10) Pub. No.: US 2024/0414953 A1
(43) Pub. Date: Dec. 12, 2024

(54) SEMICONDUCTOR DEVICE AND DISPLAY DEVICE

(71) Applicant: Sony Semiconductor Solutions Corporation, Kanagawa (JP)

(72) Inventors: Hiroshi Fujimaki, Kanagawa (JP); Hiroshi Nishikawa, Kanagawa (JP)

(21) Appl. No.: 18/699,530

(22) PCT Filed: Nov. 22, 2022
(86) PCT No.: PCT/JP2022/043206

§ 371 Date: Apr. 8, 2024

(30) Foreign Application Priority Data
Nov. 29, 2021 (JP) 2021-193295

(51) Int. Cl. H10K 59/122; G09G 3/3233; H10K 59/80

(52) U.S. Cl. CPC H10K 59/122; H10K 59/8792; G09G 3/3233; G09G 2300/0852; G09G 2310/08; G09G 2320/0242

(57) ABSTRACT

A semiconductor device according to an embodiment includes: a plurality of pixels arrayed in a two-dimensional matrix shape; and a partition wall disposed between the pixels, the partition wall partitioning each of the pixels, in which each of the pixels includes: a first electrode provided on a substrate; an antireflection film provided on at least a part of a peripheral portion of the first electrode; a light emitting layer provided on the first electrode; and a second electrode provided on the light emitting layer.

### FIELD

The present disclosure relates to a semiconductor device and a display device.

### BACKGROUND

In recent years, organic electroluminescence (EL) (hereinafter, also referred to as organic light-emitting diodes (OLEDs)) devices are applied not only to direct-view displays such as monitors and smartphones but also to ultra-small displays (microdisplays) requiring a pixel pitch of several microns, and implementation to applications such as augmented reality (AR) or virtual reality (VR) has been studied. In addition, in applications such as VR, high definition and a wide color gamut are desired in order to enjoy video.

### CITATION LIST

### Patent Literature

Patent Literature 1: JP 2013-45766 A

### SUMMARY

### Technical Problem

In an OLED device, a structure is generally used in which an electrode is imparted with a reflector function in order to extract emitted light, and there is an insulating partition wall for pixel separation, which covers up to an upper portion of the electrode to define a light emitting region. As a material of the partition wall, an organic substance such as polyimide (PI) or an inorganic substance such as silicon nitride (SiN) or silicon oxide (SiOx) is generally used. These are basically transparent materials.

There is also technology of selectively coating with an organic material (selective mask coating or the like); however, since the positional accuracy thereof is worse than the accuracy of processing the partition wall by photolithography, as described above, the structure in which the light emitting region is defined by the partition wall for pixel separation is generally used. Therefore, the organic material is deposited also on the partition wall.

In a case where an organic material is deposited including the partition wall, since the organic material has a charge transporting property, charges are transported even to the partition wall portion (lateral direction) to emit light (edge light emission), and an electrode under the partition wall functions as a reflector, whereby an interference color that is not designed is generated. In addition, light propagated laterally in the partition wall may be reflected by an electrode of an adjacent pixel and extracted as stray light. When such undesigned light is extracted to the outside, this leads to a decrease in color purity, which is a problem for achieving a wide color gamut.

Therefore, the present disclosure proposes a semiconductor device and a display device capable of suppressing narrowing of a color gamut due to a decrease in color purity.

### Solution to Problem

A semiconductor device according to one embodiment of the present disclosure includes: a plurality of pixels arrayed in a two-dimensional matrix shape; and a partition wall disposed between the pixels, the partition wall partitioning each of the pixels, wherein each of the pixels includes: a first electrode provided on a substrate; an antireflection film provided on at least a part of a peripheral portion of the first electrode; a light emitting layer provided on the first electrode; and a second electrode provided on the light emitting layer.

### BRIEF DESCRIPTION OF DRAWINGS

FIG. 1 is a schematic diagram illustrating an overall configuration of a display device according to an embodiment of the present disclosure.

FIG. 2 is a schematic diagram illustrating configurations of a pixel unit, a scanning unit, and a selection unit illustrated in FIG. 1 in more detail.

FIG. 3 is a schematic diagram illustrating a configuration of a pixel circuit 210 illustrated in FIG. 2.

FIG. 4 is a diagram for explaining the operation of the pixel circuit 210 according to the embodiment of the disclosure.

FIG. 5 is a vertical cross-sectional view illustrating a cross-sectional structure example of a pixel in the display device 1 according to the embodiment of the disclosure.

FIG. 6 is a vertical cross-sectional view illustrating a partial cross-sectional structure example of a pixel in the display device 1 according to the first embodiment.

FIG. 7 is a vertical cross-sectional view illustrating a partial cross-sectional structure example of a pixel in a display device 1 according to a second embodiment.

FIG. 8 is a vertical cross-sectional view illustrating a partial cross-sectional structure example of a pixel in a display device 1 according to a third embodiment.

FIG. 9 is a vertical cross-sectional view illustrating a partial cross-sectional structure example of a pixel in a display device 1 according to a modification of the third embodiment.

FIG. 10 is a vertical cross-sectional view illustrating a partial cross-sectional structure example of a pixel in a display device 1 according to a fourth embodiment.

FIG. 11 is a vertical cross-sectional view illustrating a partial cross-sectional structure example of a pixel in a display device 1 according to a fifth embodiment.

FIG. 12 is a vertical cross-sectional view illustrating a partial cross-sectional structure example of a pixel in a display device 1 according to a sixth embodiment.

FIG. 13 is a vertical cross-sectional view illustrating a partial cross-sectional structure example of a pixel in a display device 1 according to a seventh embodiment.

FIG. 14 is a vertical cross-sectional view illustrating a partial cross-sectional structure example of a pixel in a display device 1 according to an eighth embodiment.

FIG. 15 is a plan view illustrating a partial planar structure example of a pixel according to a first example of a ninth embodiment.

FIG. 16 is a plan view illustrating a partial planar structure example of a pixel according to a second example of the ninth embodiment.

FIG. 17 is a plan view illustrating a partial planar structure example of a pixel according to a third example of the ninth embodiment.

FIG. 18 is a plan view illustrating a partial planar structure example of a pixel according to a fourth example of the ninth embodiment.

FIG. 19 is a plan view illustrating a partial planar structure example of a pixel according to a fifth example of the ninth embodiment.

FIG. 20 is a front view of a digital still camera of a lens interchangeable mirrorless type to which the display device according to a tenth embodiment is applied.

FIG. 21 is a rear view of the digital still camera of the lens interchangeable mirrorless type to which the display device according to the tenth embodiment is applied.

FIG. 22 is an external view of a head mounted display to which the display device according to the tenth embodiment is applied.

### DESCRIPTION OF EMBODIMENTS

Hereinafter, embodiments of the present disclosure will be described in detail on the basis of the drawings. Note that in each of the following embodiments, the same parts are denoted by the same symbols, and redundant description will be omitted.

The present disclosure will be described in the following order of items.
1. Description of Display Device
1.1 Overall Configuration Example of Display Device
1.2 Configuration Example of Pixel Circuit
1.3 Operation Example of Pixel Circuit
1.4 Cross-Sectional Structure Example of Pixel
2. First Embodiment
3. Second Embodiment
4. Third Embodiment
4.1 Modifications
5. Fourth Embodiment
6. Fifth Embodiment
7. Sixth Embodiment
8. Seventh Embodiment
9. Eighth Embodiment
10. Ninth Embodiment
10.1 First Example
10.2 Second Example
10.3 Third Example
10.4 Fourth Example
10.5 Fifth Example
11. Tenth Embodiment

### 1. Description of Display Device

In describing embodiments according to the present disclosure, display devices according to the following embodiments will be described in detail with reference to the drawings. Note that semiconductor devices according to the following embodiment are not limited to a display device and may be applied to various devices that emit light, such as a lighting system.

### 1.1 Overall Configuration Example of Display Device

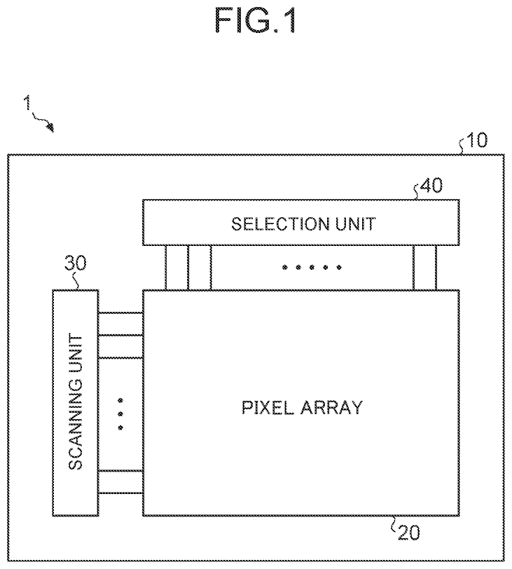

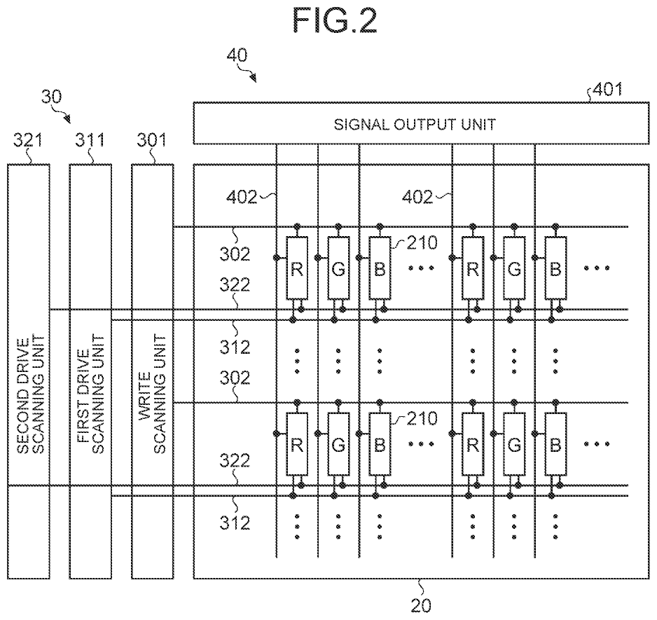

First, an overall configuration of display devices according to the following embodiments will be described with reference to FIGS. 1 and 2. FIG. 1 is a schematic diagram illustrating an overall configuration of a display device according to an embodiment. FIG. 2 is a schematic diagram illustrating configurations of a pixel unit, a scanning unit, and a selection unit illustrated in FIG. 1 in more detail.

Referring to FIG. 1, a display device 1 includes a pixel array 20, a scanning unit 30, and a selection unit 40 arranged on a display panel 10. As illustrated in FIG. 2, the pixel array 20 includes a plurality of pixel circuits 210 arrayed in a matrix shape. Note that, although it is described as pixel circuit 210 for convenience, a “pixel circuit 210” illustrated in FIG. 2 indicates a portion of the pixel circuit 210 excluding a wiring layer, and in practice, each piece of wiring (wiring extending from the scanning unit 30 or the selection unit 40 to be described later, a power supply line 332, and others) is connected to the “pixel circuit 210” illustrated in FIG. 2, whereby the pixel circuit 210 can be configured. That is, these pieces of wiring can be provided in a shared manner for a plurality of pixel circuits 210 but can also constitute a part of a pixel circuit 210, and thus, in FIG. 2, a portion of a pixel circuit 210 excluding the wiring layer is illustrated as a pixel circuit 210 for convenience. In a case where it is herein described as a pixel circuit 210, as described above, only a portion excluding the wiring layer thereof may be referred to for convenience.

One pixel circuit 210 corresponds to one sub-pixel. Incidentally, the display device 1 is capable of performing color display, and one pixel serving as a unit for forming a color image includes a plurality of sub-pixels. Specifically, one pixel includes three sub-pixels of a sub-pixel that emits red light, a sub-pixel that emits green light, and a sub-pixel that emits blue light. In FIG. 2, a color (R, G, or B) corresponding to each sub-pixel is denoted in each pixel circuit 210 in a simulated manner. By appropriately controlling light emission in each pixel circuit 210 (namely, each sub-pixel), a desired image is displayed in the pixel array 20. In this manner, the pixel array 20 corresponds to a display plane in the display device 1.

However, in the following embodiments, the combination of sub-pixels included in one pixel is not limited to the combination of sub-pixels of the three primary colors of RGB. For example, one pixel can be constituted by further adding one or a plurality of colors of sub-pixels to the sub-pixels of the three primary colors. Specifically, for example, one pixel can be constituted by adding a sub-pixel that emits white light to sub-pixels of the three primary colors in order to improve luminance, or one pixel can be constituted by adding at least one sub-pixel that emits complementary color light to sub-pixels of the three primary colors in order to expand a color reproduction range. Alternatively, the display device 1 may be configured such that there are no sub-pixels and that one pixel circuit 210 corresponds to one pixel. Further alternatively, the display device 1 may not be capable of performing color display and may perform monochrome display.

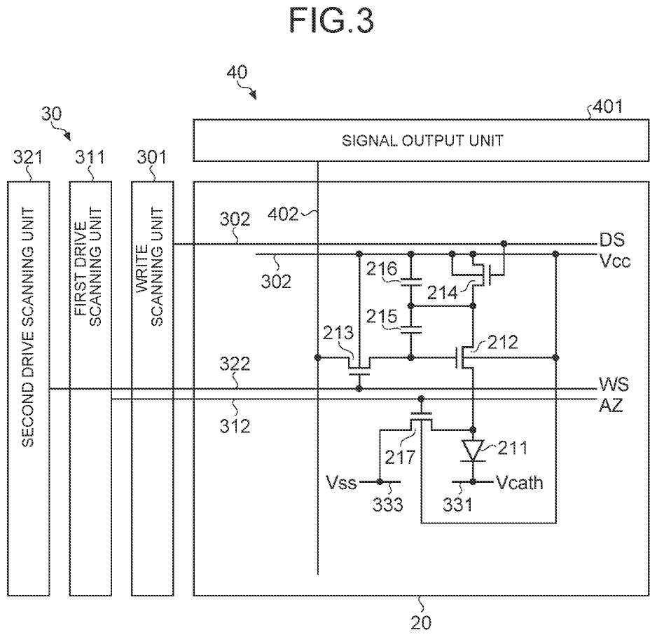

The scanning unit 30 is arranged on one side in the horizontal direction of the pixel array 20. From the scanning unit 30, a plurality of pieces of wiring arrayed in the vertical direction extend in the horizontal direction toward the pixel array 20. Specifically, as illustrated in FIG. 2, the scanning unit 30 includes a write scanning unit 301, a first drive scanning unit 311, and a second drive scanning unit 321. A plurality of scanning lines 302 extends from the write scanning unit 301 toward respective rows of pixel circuits 210, a plurality of first drive lines 312 extends from the first drive scanning unit 311 toward respective rows of the pixel circuits 210, and a plurality of second drive lines 322 extend from the second drive scanning unit 321 toward respective rows of the pixel circuits 210. The plurality of pieces of wiring (the scanning lines 302, the first drive lines 312, and the second drive lines 322) is connected to respective pixel circuits 210. The write scanning unit 301, the first drive scanning unit 311, and the second drive scanning unit 321 control the operation of each pixel circuit 210 such that a desired image can be displayed on the display plane as a whole by appropriately changing the potentials of the plurality of pieces of wiring. Details of the connection state of a scanning line 302, a first drive line 312, and a second drive line 322 with a pixel circuit 210 and functions of the write scanning unit 301, the first drive scanning unit 311, and the second drive scanning unit 321 will be described later with reference to FIG. 3.

The selection unit 40 is disposed on one side of the pixel array 20 in the vertical direction. From the selection unit 40, a plurality of pieces of wiring arrayed in the horizontal direction extends in the vertical direction toward the pixel array 20. Specifically, as illustrated in FIG. 2, the selection unit 40 includes a signal output unit 401. A plurality of signal lines 402 extends from the signal output unit 401 toward respective columns of pixel circuits 210. The plurality of signal lines 402 is connected to the respective pixel circuits 210 in the pixel array 20. The signal output unit 401 controls the operation of each pixel circuit 210 such that a desired image can be displayed on the display plane as a whole by appropriately changing the potentials of the plurality of signal lines 402. Details of the connection state between a signal line 402 and a pixel circuit 210 and the function of the signal output unit 401 will be described later with reference to FIG. 3.

In this manner, the pieces of wiring extending in the horizontal direction from the scanning unit 30 are provided corresponding to respective rows of the pixel circuits 210 arrayed in the matrix shape and are connected to the respective pixel circuits 210. Furthermore, the pieces of wiring extending in the vertical direction from the selection unit 40 are provided corresponding to respective columns of the pixel circuits 210 arranged in the matrix shape and are connected to the respective pixel circuits 210. Moreover, by appropriately changing the potentials of the plurality of pieces of wiring by the scanning unit 30 and the selection unit 40, the operation of each pixel circuit of the pixel array 20 is controlled.

### 1.2 Configuration Example of Pixel Circuit

Next, a configuration example of a pixel circuit 210 illustrated in FIG. 2 will be described with reference to FIG. 3. FIG. 3 is a schematic diagram illustrating a configuration of a pixel circuit 210 illustrated in FIG. 2. In FIG. 3, illustrated is a circuit configuration of one pixel circuit 210 among the plurality of pixel circuits 210 illustrated in FIG. 2, and also illustrated are connection states of scanning lines 302, a first drive line 312, a second drive line 322, and a signal line 402 with respect to the pixel circuit 210.

As illustrated in FIG. 3, the pixel circuit 210 includes an organic light emitting diode 211 that is a light emitting element and a drive circuit that drives the organic light emitting diode 211 by causing a current to flow through the organic light emitting diode 211. The drive circuit includes four transistors (drive transistor 212, sampling transistor 213, light emission control transistor 214, and switching transistor 217) as active elements and capacitive elements (holding capacitor 215 and auxiliary capacitor 216). The pieces of wiring (the scanning lines 302, the first drive line 312, the second drive line 322, the signal line 402, and the power supply line 332 to be described later, and others) are connected to these elements, whereby the pixel circuit 210 is configured.

Note that, as the organic light emitting diode 211, an organic light emitting diode having a general structure can be used. Furthermore, the drive transistor 212, the sampling transistor 213, the light emission control transistor 214, and the switching transistor 217 are P-channel type four-terminal (source, gate, drain, and back gate) transistors formed on a semiconductor such as silicon, and a structure thereof may be similar to that of a general P-channel type four-terminal transistor. Therefore, the detailed description of the structures of the organic light emitting diode 211, the drive transistor 212, the sampling transistor 213, the light emission control transistor 214, and the switching transistor 217 is omitted here.

The cathode electrode of the organic light emitting diode 211 is connected to the common power supply line 331 (potential: V_{OATH}) provided in a shared manner for all the pixel circuits 210 of the pixel array 20. A drain electrode of the drive transistor 212 is connected to an anode electrode of the organic light emitting diode 211.

A drain electrode of the light emission control transistor 214 is connected to a source electrode of the drive transistor 212, and a source electrode of the light emission control transistor 214 is connected to the power supply line 332 (potential: V_{cc}, V_{cc} is power supply potential). Furthermore, a gate electrode of the drive transistor 212 is connected to a drain electrode of the sampling transistor 213, and a source electrode of the sampling transistor 213 is connected to the signal line 402.

Therefore, by bringing the sampling transistor 213 into a conductive state, a potential corresponding to the potential of the signal line 402 is applied to the gate electrode of the drive transistor 212 (the potential of the signal line 402 is written), and the drive transistor 212 is brought into a conductive state. Furthermore, at this point, by bringing the light emission control transistor 214 into the conductive state, a potential corresponding to the signal potential V_{cc} is applied to the source electrode of the drive transistor 212, a drain-source current I_{ds}, is generated in the drive transistor 212, and the organic light emitting diode 211 is driven. At this point, since the magnitude of the drain-source current I_{ds} varies depending on a gate potential V_{g} of the drive transistor 212, the light emission luminance of the organic light emitting diode 211 is controlled depending on the gate potential V_{g} of the drive transistor 212, namely, the potential of the signal line 402 written by the sampling transistor 213.

As described above, the drive transistor 212 has a function of driving the organic light emitting diode 211 by its drain-source current I_{ds}. In addition, the sampling transistor 213 has a function of writing the potential of the signal line 402 to the pixel circuit 210 by controlling the gate voltage of the drive transistor 212 depending on the potential of the signal line 402, namely, controlling on/off of the drive transistor 212 (that is, the sampling transistor 213 has a function of sampling the pixel circuit 210 in which the potential of the signal line 402 is written). Furthermore, the light emission control transistor 214 has a function of controlling the drain-source current I_{ds} of the drive transistor 212 by controlling the potential of the source electrode of the drive transistor 212 and controlling light emission and non-light emission of the organic light emitting diode 211.

The holding capacitor 215 is connected between the gate electrode of the drive transistor 212 (namely, the drain electrode of the sampling transistor 213) and the source electrode of the drive transistor 212. That is, the holding capacitor 215 holds the gate-source voltage V_{gs} of the drive transistor 212. The auxiliary capacitor 216 is connected between the source electrode of the drive transistor 212 and the power supply line 332. The auxiliary capacitor 216 performs action of suppressing fluctuations in the source potential of the drive transistor 212 when the potential of the signal line 402 is written.

The signal output unit 401 appropriately controls the potential of the signal line 402 (signal line voltage Date) to write the potential of the signal line 402 into the pixel circuit 210 (specifically, as described above, the potential of the signal line 402 is written to the pixel circuit 210 selected by the sampling transistor 213). In the following embodiment, the signal output unit 401 selectively outputs a signal voltage V_{sig} corresponding to a video signal, a first reference voltage V_{ref}, and a second reference voltage V_{ofs} via the signal line 402. Incidentally, the first reference voltage V_{ref} is a reference voltage for reliably quenching the organic light emitting diode 211. In addition, the second reference voltage V_{ofs} is a voltage (for example, a voltage corresponding to the black level of the video signal) serving as a reference of the signal voltage V_{sig} corresponding to the video signal and is used when a threshold value correction operation to be described later is performed.

A scanning line 302 is connected to a gate electrode of the sampling transistor 213. The write scanning unit 301 controls on and off of the sampling transistor 213 by changing the potential of the scanning line 302 (scanning line voltage WS) and executes processing of writing the potential of the signal line 402 (for example, the signal voltage V_{sig} corresponding to the video signal) to the pixel circuit 210. In practice, as described with reference to FIG. 2, the plurality of scanning lines 302 is extended to the respective rows of the plurality of pixel circuits 210 arrayed in the matrix shape. When the potential of the signal line 402 is written to each pixel circuit 210, the write scanning unit 301 sequentially supplies the scanning line voltage WS of a predetermined value to the plurality of scanning lines 302, thereby sequentially scanning each pixel circuit 210 row by row.

Note that, regarding the signal line 402, in practice, as described with reference to FIG. 2, the plurality of signal lines 402 is extended to respective columns of the plurality of pixel circuits 210 arrayed in the matrix shape. The signal voltage V_{sig} corresponding to the video signal, the first reference voltage V_{ref}, and the second reference voltage V_{ofs} which are selectively output from the signal output unit 401 are written to each pixel circuit 210 via the plurality of signal lines 402 pixel row by pixel row selected by scanning by the write scanning unit 301. That is, the signal output unit 401 writes the potential of the signal line 402 row by row.

The first drive line 312 is connected to the gate electrode of the light emission control transistor 214. The first drive scanning unit 311 controls on and off of the light emission control transistor 214 by changing the potential (first drive line voltage DS) of the first drive line 312 and executes processing of controlling light emission and non-light emission of the organic light emitting diode 211 described above. In practice, as described with reference to FIG. 2, the plurality of first drive lines 312 is extended to the respective rows of the plurality of pixel circuits 210 arrayed in the matrix shape. The first drive scanning unit 311 sequentially supplies the first drive line voltage DS of a predetermined value to the plurality of first drive lines 312 in synchronization with scanning by the write scanning unit 301, thereby appropriately controlling light emission and non-light emission of each pixel circuit 210.

Meanwhile, in the pixel circuit 210, the source electrode of the switching transistor 217 is connected to the anode electrode of the organic light emitting diode 211. A drain electrode of the switching transistor 217 is connected to a ground line 333 (potential: Vₛₛ, Vₛₛ is ground potential). By a current path formed by the switching transistor 217, the current flowing through the drive transistor 212 during a non-light emitting period of the organic light emitting diode 211 flows to the ground line 333.

When the pixel circuit 210 according to the following embodiment is driven, a threshold value correction operation for correcting a threshold voltage Vₜₕ of the drive transistor 212 is performed, and furthermore, a threshold value correction preparation operation is performed as a previous stage of performing the threshold value correction operation. In such a threshold value correction preparation operation, an operation of initializing the gate potential V_{g} and a source potential Vₛ of the drive transistor 212 is performed, and as a result, the gate-source voltage V_{gs} of the drive transistor 212 becomes larger than the threshold voltage Vₜₕ of the drive transistor 212. This is because the threshold value correction operation cannot be performed correctly unless the gate-source voltage V_{gs} of the drive transistor 212 is made larger than the threshold voltage Vₜₕ of the drive transistor 212.

Therefore, when the operation of initializing the gate potential V_{g} and the source potential Vₛ of the drive transistor 212 is performed, an anode potential Vₐₙₒ of the organic light emitting diode 211 may exceed a threshold voltage Vₜₕₑₗ of the organic light emitting diode 211 even during the non-light emitting period of the organic light emitting diode 211. Then, a current flows from the drive transistor 212 into the organic light emitting diode 211, and a phenomenon occurs in which the organic light emitting diode 211 emits light even in the non-light emitting period.

Therefore, in the following embodiments, in order to prevent such a phenomenon, a current circuit by the above-described switching transistor 217 is included. As a result, the current from the drive transistor 212 flows into such a current circuit without flowing into the organic light emitting diode 211, whereby unintended light emission of the organic light emitting diode 211 can be prevented.

The second drive line 322 is connected to a gate electrode of the switching transistor 217. The second drive scanning unit 321 controls on and off of the switching transistor 217 by changing the potential (second drive line voltage AZ) of the second drive line 322. Specifically, by appropriately changing the second drive line voltage AZ, the second drive scanning unit 321 performs, more specifically, at least the threshold value correction preparation operation during the non-light emitting period and, during a period in which the gate-source voltage V_{gs} of the drive transistor 212 is larger than the threshold voltage Vₜₕ of the drive transistor 212, brings the switching transistor 217 to a conductive state to open the current circuit. In practice, as described with reference to FIG. 2, the plurality of second drive lines 322 is extended to the respective rows of the plurality of pixel circuits 210 arrayed in the matrix shape. The second drive scanning unit 321 sequentially supplies the second drive line voltage AZ having a predetermined value to the plurality of second drive lines 322 in synchronization with the scanning by the write scanning unit 301, thereby appropriately controlling the driving of the switching transistor 217 such that the switching transistor 217 is in the conductive state during the above period.

Note that the write scanning unit 301, the first drive scanning unit 311, the second drive scanning unit 321, and the signal output unit 401 can be configured by various circuits capable of implementing the above-described functions, such as a shift register circuit, using a known method, and thus, a detailed description of the circuit configuration thereof will be omitted here.

### 1.3 Operation Example of Pixel Circuit

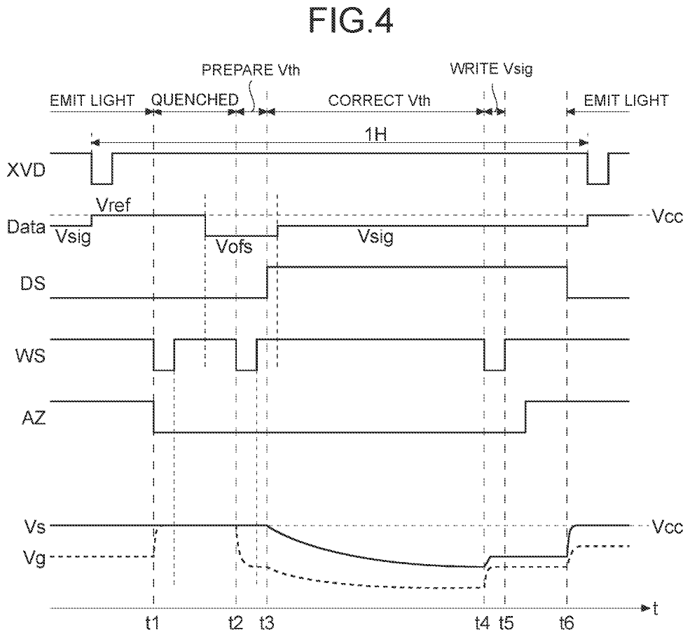

An operation example of the pixel circuit 210 described above will be described. FIG. 4 is a diagram for explaining the operation of a pixel circuit 210 according to the following embodiments. In FIG. 4, illustrated is a timing waveform diagram of signals related to the operation of the pixel circuit 210. Specifically, illustrated in FIG. 4 are changes of the potential of the signal line 402 (signal line voltage Date), the potential of the scanning line 302 (scanning line voltage WS), the potential of the first drive line 312 (first drive line voltage DS), the potential of the second drive line 322 (second drive line voltage AZ), the source potential Vₛ of the drive transistor 212, and the gate potential V_{g} of the drive transistor 212 change in one horizontal period (1H period).

Note that, since the sampling transistor 213, the light emission control transistor 214, and the switching transistor 217 are P-channel transistors, these transistors are in an on-state, namely, the conductive state when the scanning line voltage WS, the first drive line voltage DS, and the second drive line voltage AZ are in a state of a low potential, and these transistors are in an off-state, namely, a non-conductive state when the scanning line voltage WS, the first drive line voltage DS, and the second drive line voltage AZ are in a state of a high potential. Similarly for the drive transistor 212, the drive transistor 212 is in a conductive state when the gate potential V_{g} is a low potential, and the drive transistor 212 is in a non-conductive state when the gate potential V_{g} is a high potential. Furthermore, as described above, for the signal line voltage Date, any one of the signal voltage V_{sig}, the first reference voltage V_{ref}, and the second reference voltage V_{ofs} corresponding to the video signal is alternatively selected. In the waveform diagram illustrated in FIG. 4, as an example, V_{ref}=V_{cc} (power supply potential) holds.

At the end of the light emitting period of the organic light emitting diode 211, the scanning line voltage WS transitions from a high potential to a low potential, and the sampling transistor 213 is brought into the conductive state (time t₁). Meanwhile, at time t₁, the signal line voltage Date is controlled to the first reference voltage V_{ref}. Therefore, as the scanning line voltage WS transitions from the high potential to the low potential, the gate-source voltage V_{gs} of the drive transistor 212 becomes equal to or lower than the threshold voltage Vₜₕ of the drive transistor 212, and thus the drive transistor 212 is cut off. When the drive transistor 212 is cut off, a current supply path to the organic light emitting diode 211 is cut off, and thus the anode potential Vₐₙₒ of the organic light emitting diode 211 gradually decreases. Eventually, when the anode potential Vₐₙₒ becomes equal to or lower than the threshold voltage Vₜₕₑₗ of the organic light emitting diode 211, the organic light emitting diode 211 enters a completely quenched state (period from time t₁ to t₂: quenched period).

After the quenched period, a period for performing a preparation operation (threshold value correction preparation operation) before performing the threshold value correction operation to be described later is provided (period from time t₂ to time t₃ threshold value correction preparation period). Specifically, at time t₂, which is the timing when the threshold value correction preparation period is started, the scanning line voltage WS transitions from the high potential to the low potential, whereby the sampling transistor 213 enters the conductive state. Meanwhile, at time t₂, the signal line voltage Date is controlled to the second reference voltage V_{ofs}. As the sampling transistor 213 is brought to the conductive state in a state where the signal line voltage Date is the second reference voltage V_{ofs}, the gate potential V_{g} of the drive transistor 212 becomes the second reference voltage V_{ofs}.

Moreover, at time t₂, the first drive line voltage DS is in a low potential state, and the light emission control transistor 214 is in the conductive state. Therefore, the source potential Vₛ of the drive transistor 212 becomes the power supply voltage V_{cc}. At this point, the gate-source voltage V_{gs} of the drive transistor 212 is:

$${V}_{gs} = {V}_{ofs} - {V}_{cc} .$$

At this point, in order to perform the threshold value correction operation, it is necessary to make the gate-source voltage V_{gs} of the drive transistor 212 larger than the threshold voltage Vₜₕ of the drive transistor 212. Therefore, each voltage value is set such that |V_{g}|=|V_{ofs}−V_{cc}|>|Vₜₕ| holds.

As described above, the initialization operation of setting the gate potential V_{gs} of the drive transistor 212 to the second reference voltage V_{ofs} and setting the source potential Vₛ of the drive transistor 212 to the power supply voltage V_{cc} is the threshold value correction preparation operation. That is, the second reference voltage V_{ofs} and the power supply voltage V_{cc} are initialization voltages of the gate potential V_{g} and the source potential Vₛ of the drive transistor 212, respectively.

When the threshold value correction preparation period ends, next, the threshold value correction operation for correcting the threshold voltage Vₜₕ of the drive transistor 212 is performed (period from time t₃ to time t₄: threshold value correction period). In the period during which the threshold value correction operation is performed, first, the first drive line voltage DS transitions from the low potential to the high potential at time t₃, which is the timing when the threshold value correction period is started, and the light emission control transistor 214 enters the non-conductive state. As a result, the source potential Vₛ of the drive transistor 212 enters a floating state. Meanwhile, at time t₃, the scanning line voltage WS is controlled to the high potential, and the sampling transistor 213 is in the non-conductive state. Therefore, at time t₃, the gate potential V_{g} of the drive transistor 212 also enters the floating state, and the source electrode and the gate electrode of the drive transistor 212 are connected to each other via the holding capacitor 215 in the floating state. As a result, as illustrated, the source potential Vₛ and the gate potential V_{g} of the drive transistor 212 gradually change to predetermined values corresponding to the threshold voltage Vₜₕ of the drive transistor 212.

In this manner, the operation of changing the source potential Vₛ and the gate potential V_{g} of the drive transistor 212 to predetermined values corresponding to the threshold voltage Vₜₕ of the drive transistor 212 in the floating state with reference to the initialization voltage V_{ofs} of the gate potential V_{g} of the drive transistor 212 and the initialization voltage V_{cc} of the source potential V_{ofs} of the drive transistor 212 is the threshold value correction operation. As the threshold value correction operation proceeds, the gate-source voltage V_{gs} of the drive transistor 212 eventually converges to the threshold voltage Vₜₕ of the drive transistor 212. The voltage corresponding to the threshold voltage Vₜₕ is held in the holding capacitor 215.

Note that the threshold voltage Vₜₕ of the drive transistor 212 naturally has a design value; however, the actual threshold voltage Vₜₕ does not necessarily coincide with the design value due to manufacturing variations and others. For this, by performing the threshold value correction operation as described above, a voltage corresponding to the actual threshold voltage Vₜₕ can be held in the holding capacitor 215 before the organic light emitting diode 211 is caused to emit light. As a result, as described later, when the drive transistor 212 is driven to cause the organic light emitting diode 211 to emit light thereafter, it is possible to cancel variations in the threshold voltage Vₜₕ of the drive transistor 212. Therefore, the driving of the drive transistor 212 can be controlled more accurately, and a desired luminance can be more suitably obtained.

When the threshold value correction period ends, next, a signal writing operation of writing the signal voltage V_{sig}, corresponding to the video signal is performed (period from time t₄ to time t₅: signal writing period). In the signal writing period, the scanning line voltage WS transitions from the high potential to the low potential at time t₄, which is the timing when the signal writing period is started, and the sampling transistor 213 is brought into the conductive state. Meanwhile, at time t₄, since the signal line voltage Date is controlled to the signal voltage V_{sig} corresponding to the video signal, the signal voltage V_{sig} corresponding to the video signal is written in the holding capacitor 215. When the signal voltage V_{sig} corresponding to the video signal is written, the auxiliary capacitor 216 connected between the source electrode of the drive transistor 212 and the power supply line 332 plays a role of suppressing fluctuation of the source potential Vₛ of the drive transistor 212. Then, when the signal voltage V_{sig} corresponding to the video signal is written, namely, when the signal voltage V_{sig} corresponding to the video signal is applied to the gate electrode of the drive transistor 212 and the drive transistor 212 is driven, the threshold voltage Vₜₕ of the drive transistor 212 is offset by the voltage corresponding to the threshold voltage Vₜₕ held in the holding capacitor 215 in the threshold value correction operation. That is, by performing the threshold value correction operation, variations in the threshold voltage Vₜₕ of the drive transistors 212 for the respective pixel circuits 210 are canceled.

At time t₅, the scanning line voltage WS transitions from the low potential to the high potential, and the sampling transistor 213 is brought into the non-conductive state, whereby the signal writing period ends. When the signal writing period ends, next, a light emitting period is started from time t₆. At time t₆, which is the timing when the light emitting period is started, the first drive line voltage DS transitions from the high potential to the low potential, whereby the light emission control transistor 214 is brought into the conductive state. As a result, a current is supplied from the power supply line 332 having the power supply voltage V_{cc} to the source electrode of the drive transistor 212 via the light emission control transistor 214.

At this point, since the sampling transistor 213 is in the non-conductive state, the gate electrode of the drive transistor 212 is electrically disconnected from the signal line 402 and is in the floating state. When the gate electrode of the drive transistor 212 is in the floating state, since the holding capacitor 215 is connected between the gate and the source of the drive transistor 212, the gate potential V_{g} also fluctuates in conjunction with the fluctuation of the source potential Vₛ of the drive transistor 212. That is, the source potential Vₛ and the gate potential V_{g} of the drive transistor 212 increase while the gate-source voltage V_{gs} held in the holding capacitor 215 is held. Then, the source potential Vₛ of the drive transistor 212 rises to a light emission voltage V_{oled} of the organic light emitting diode 211 corresponding to the saturation current of the transistor.

The operation in which the gate potential V_{g} of the drive transistor 212 fluctuates in conjunction with the fluctuation of the source potential Vₛ as described above is referred to as bootstrap operation. In other words, the bootstrap operation is an operation in which the gate potential V_{g} and the source potential Vₛ of the drive transistor 212 fluctuate while the gate-source voltage V_{gs} held in the holding capacitor 215, namely, the voltage between both terminals of the holding capacitor 215 is held.

Then, as the drain-source current I_{ds} of the drive transistor 212 starts flowing to the organic light emitting diode 211, the anode potential Vₐₙₒ of the organic light emitting diode 211 increases depending on the drain-source current I_{ds}. Eventually, when the anode potential Vₐₙₒ of the organic light emitting diode 211 exceeds the threshold voltage Vₜₕₑ of the organic light emitting diode 211, a drive current starts flowing through the organic light emitting diode 211, and the organic light emitting diode 211 starts emitting light.

The operation described above is executed in each pixel circuit 210 within the 1H period. Note that, as described above, since the switching transistor 217 is for preventing unintended light emission of the organic light emitting diode 211 caused by a current flowing from the drive transistor 212 toward the organic light emitting diode 211 in the non-light emitting period, the second drive line voltage AZ is controlled as appropriate such that the switching transistor 217 is in the conductive state in the non-light emitting period. In the illustrated example, the second drive line voltage AZ transitions from the high potential to the low potential at time t₁ when the light emitting period ends, and the second drive line voltage AZ transitions from the low potential to the high potential immediately before time t₆ when the next light emitting period is started.

Note that the overall configuration of the display device 1, the configuration of the pixel circuits 210, and the operation of the pixel circuits 210 described above are merely examples, and the present disclosure is not limited to such examples. For example, various known configurations used in a general display device may be applied as appropriate to the display devices 1 according to the following embodiments as necessary.

### 1.4 Cross-Sectional Structure Example of Pixel

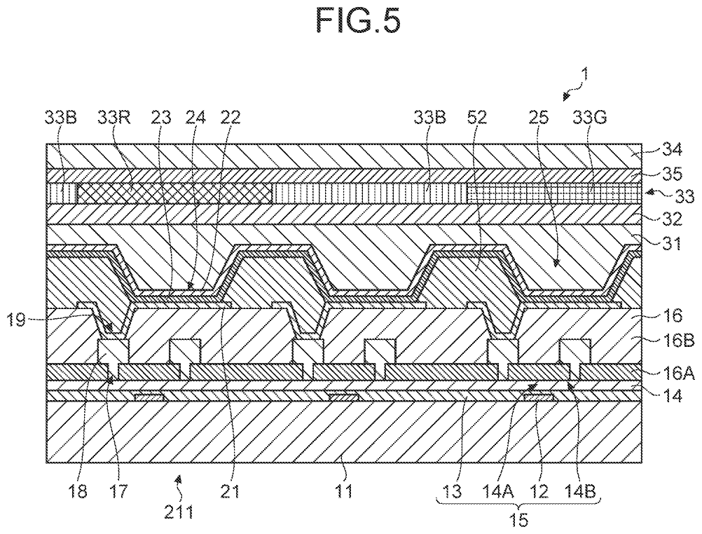

Next, a cross-sectional structure example of a pixel in the above-described display device 1 will be described. FIG. 5 is a vertical cross-sectional view illustrating a cross-sectional structure example of a pixel in a display device 1 according to the following embodiments. Note that, note that, in the present description and the following description, the term vertical may mean being vertical to the array plane of the pixels (for example, the pixel circuits 210) in the pixel array 20 (see FIG. 1). Furthermore, in FIG. 5, illustrated is a partial cross-sectional structure example of a pixel including an organic light emitting diode 211 in the display device 1.

Referring to FIG. 5, a pixel in a display device 1 according to the following embodiments includes, on a first substrate 11, a plurality of organic light emitting diodes 211 which are light emitting elements that emit white light and a CF layer 33 which is provided above the organic light emitting diodes 211 and in which color filters (CF) of different colors are formed corresponding to respective organic light emitting diodes 211. A second substrate 34 made of a material transparent with respect to light from the organic light emitting diodes 211 is disposed above the CF layer 33. Furthermore, the first substrate 11 is provided with thin film transistors (TFT) 15 for driving the organic light emitting diodes 211 respectively corresponding to the organic light emitting diodes 211. The TFTs 15 respectively correspond to the transistors (the drive transistor 212, the sampling transistor 213, the light emission control transistor 214, and the switching transistor 217) included in the above-described pixel circuit. A desired organic light emitting diode 211 is selectively driven by a TFT 15, and the light from the driven organic light emitting diode 211 passes through a corresponding CF, whereby the color of the light is converted as appropriate, and the light is emitted from the above via the second substrate 34, whereby a desired image, characters, and others are displayed.

Note that, in the following description, the stacking direction of the layers in the display device 1 is also referred to as an up-down direction. In this case, a direction in which the first substrate 11 is disposed is defined as a downward direction, and a direction in which the second substrate 34 is disposed is defined as an upward direction. A plane perpendicular to the up-down direction is also referred to as a horizontal plane.

As described above, the display device 1 illustrated in FIG. 5 is a top face emission type display device that can perform color display and is driven by an active matrix system. However, the following embodiments are not limited to such an example, and the display device 1 according to the following embodiments may be a bottom face emission type display device in which light is emitted via the first substrate 11.

### (First Substrate and Second Substrate)

In the illustrated structure example, the first substrate 11 is constituted by, for example, a silicon substrate. The second substrate 34 is made of quartz glass. However, the following embodiments are not limited to such an example, and various known materials may be used as the first substrate 11 and the second substrate 34. For example, the first substrate 11 and the second substrate 34 can be formed of a high strain point glass substrate, a soda glass (mixture of Na₂O, CaO, and SiO₂) substrate, a borosilicate glass (mixture of Na₂O, B₂O₃, and SiO₂) substrate, a forsterite (Mg—SiO₄) substrate, a lead glass (mixture of Na₂O, PbO, and SiO₂) substrate, various glass substrates having an insulating film formed on a surface thereof, a quartz substrate, a quartz substrate having an insulating film formed on a surface thereof, a silicon substrate having an insulating film formed on a surface thereof, or an organic polymer substrate (for example, polymethyl methacrylate (polymethyl methacrylate: PMMA), polyvinyl alcohol (PVA), polyvinylphenol (PVP), polyethersulfone (PES), polyimide, polycarbonate, polyethylene terephthalate (PET), or the like). The materials for forming the first substrate 11 and the second substrate 34 may be the same or different. However, as described above, since the display device 1 is of the top face emission type, the second substrate 34 is preferably formed of a material having high transmittance that can suitably transmit light from the organic light emitting diodes 211.

### (Light Emitting Element and Partition Wall)

An organic light emitting diode 211 includes a first electrode 21, an organic layer 23 provided on the first electrode 21, and a second electrode 22 formed on the organic layer 23. More specifically, a partition wall 52 including an opening 25 in such a manner as to expose at least a part of the first electrode 21 is stacked on the first electrode 21, and the organic layer 23 is provided on the first electrode 21 exposed at the bottom of the opening 25. That is, the organic light emitting diode 211 has a structure in which the first electrode 21, the organic layer 23, and the second electrode 22 are stacked in this order in the opening 25 of the partition wall 52. This stacked structure functions as a light emitting unit 24 of each pixel. That is, a portion of the organic light emitting diode 211 corresponding to an opening 25 of the partition wall 52 serves as a light emitting face. Furthermore, the partition wall 52 is provided between the pixels and functions as a pixel defining film that defines the area of a pixel by partitioning each pixel.

The organic layer 23 includes a light emitting layer made of an organic light emitting material and is configured to be capable of emitting white light. The specific structure of the organic layer 23 is not limited and may be various known structures. For example, the organic layer 23 can include a stacked structure of a hole transport layer, a light emitting layer, and an electron transport layer, a stacked structure of a hole transport layer and a light emitting layer also serving as an electron transport layer, a stacked structure of a hole injection layer, a hole transport layer, a light emitting layer, an electron transport layer, and an electron injection layer, or other structures. Furthermore, in a case where these stacked structures or the like are made as “tandem units”, the organic layer 23 may have a two-stage tandem structure in which a first tandem unit, a connection layer, and a second tandem unit are stacked. Alternatively, the organic layer 23 may have a tandem structure of three or more stages in which three or more tandem units are stacked. In a case where the organic layer 23 includes a plurality of tandem units, by allowing the emission color of a light emitting layer in each of the tandem units to vary among red, green, and blue, the organic layer 23 that emits white light as a whole can be obtained.

In the illustrated structure example, the organic layer 23 is formed by vacuum depositing an organic material. However, the following embodiments are not limited to such an example, and the organic layer 23 may be formed by various known methods. For example, as a method of forming the organic layer 23, a physical vapor deposition method (PVD method) such as a vacuum vapor deposition method, a printing method such as a screen printing method or an inkjet printing method, a laser transfer method of irradiating a stacked structure of a laser absorption layer and an organic layer formed on a transfer substrate with a laser to separate the organic layer on the laser absorption layer and transferring the organic layer, various coating methods, or others can be used.

The first electrode 21 functions as an anode. Since the display device 1 is of the top face emission type as described above, the first electrode 21 is formed of a material capable of reflecting light from the organic layer 23. In the illustrated structure example, the first electrode 21 is formed of an alloy of aluminum and neodymium (Al—Nd alloy). Incidentally, the film thickness of the first electrode 21 is, for example, about 0.1 μm to 1 μm. However, the following embodiments are not limited to such an example, and the first electrode 21 may be formed of various known materials used as a material of a light-reflective electrode functioning as an anode in a general organic EL display device. In addition, the film thickness of the first electrode 21 is not limited to the above example, and the first electrode 21 can be formed as appropriate within the range of the film thickness generally adopted in an organic EL display device.

For example, the first electrode 21 can be formed of a metal having a high work function such as platinum (Pt), gold (Au), silver (Ag), chromium (Cr), tungsten (W), nickel (Ni), copper (Cu), iron (Fe), cobalt (Co), or tantalum (Ta) or an alloy (for example, an Ag—Pd—Cu alloy containing silver as a main component and containing 0.3 mass % to 1 mass % of palladium (Pd) and 0.3 mass % to 1 mass % of copper, an Al—Nd alloy, or the like). Alternatively, as the first electrode 21, a conductive material having a small work function value and a high light reflectance, such as aluminum or an alloy containing aluminum, can be used. In this case, it is preferable to improve the hole injection property by, for example, providing an appropriate hole injection layer on the first electrode 21. Alternatively, the first electrode 21 can have a structure in which a transparent conductive material having excellent hole injection property such as an oxide of indium and tin (ITO) or an oxide of indium and zinc (IZO) is stacked on a dielectric multilayer film or a reflective film having high light reflectivity such as aluminum.

The second electrode 22 functions as a cathode. Since the display device 1 is of the top face emission type as described above, the second electrode 22 is formed of a material capable of transmitting light from the organic layer 23. In the illustrated structure example, the second electrode 22 is formed of an alloy of magnesium and silver (Mg—Ag alloy). Incidentally, the film thickness of the second electrode 22 is, for example, about 10 nanometers (nm). However, the following embodiments are not limited to such an example, and the second electrode 22 may be formed of various known materials used as a material of a light-transmitting-side electrode functioning as a cathode in a general organic EL display device. In addition, the film thickness of the second electrode 22 is not limited to the above example, and the second electrode 22 can be formed as appropriate within the range of the film thickness generally adopted in an organic EL display device.

For example, the second electrode 22 can be formed of aluminum, silver, magnesium, calcium (Ca), sodium (Na), strontium (Sr), an alloy of an alkali metal and silver, an alloy of an alkaline earth metal and silver (for example, an alloy of magnesium and silver (Mg—Ag alloy)), an alloy of magnesium and calcium (Mg—Ca alloy), an alloy of aluminum and lithium (Al—Li alloy), or the like. When these materials are used as a single layer, the film thickness of the second electrode 22 is, for example, about 4 nm to 50 nm. Alternatively, the second electrode 22 may have a structure in which the above-described material layer and a transparent electrode (for example, a thickness of about 30 nm to 1 μm) made of, for example, ITO or IZO are stacked from the organic layer 23 side. In the case of such a stacked structure, the thickness of the above-described material layer can be reduced to, for example, about 1 nm to 4 nm. Alternatively, the second electrode 22 may be constituted only by a transparent electrode. Alternatively, a bus electrode (auxiliary electrode) made of a low-resistance material such as aluminum, an aluminum alloy, silver, a silver alloy, copper, a copper alloy, gold, or a gold alloy may be provided for the second electrode 22 to reduce the resistance of the second electrode 22 as a whole.

In the illustrated structure example, the first electrode 21 and the second electrode 22 are formed by forming a film of a material by a predetermined thickness by the vacuum vapor deposition method and then patterning the film by the etching method. However, the following embodiments are not limited to such an example, and the first electrode 21 and the second electrode 22 may be formed by various known methods. Examples of the method of forming the first electrode 21 and the second electrode 22 include a vapor deposition method including an electron beam vapor deposition method, a hot filament vapor deposition method, and a vacuum vapor deposition method, a sputtering method, a chemical vapor deposition method (CVD method), a metal organic chemical vapor deposition method (MOCVD method), a combination of an ion plating method and an etching method, various printing methods (for example, a screen printing method, an inkjet printing method, a metal mask printing method, or the like), a plating method (electroplating method, electroless plating method, or the like), a lift-off method, a laser ablation method, a sol-gel method, and others.

The partition wall 52 is formed by depositing SiO₂ by a predetermined film thickness by the CVD method and then patterning the SiO₂ film using photolithography technology and etching technology. However, the material of the partition wall 52 is not limited to such examples, and various materials having an insulating property can be used as the material of the partition wall 52. Examples of the material for forming the partition wall 52 include SiO₂, MgF, LiF, a polyimide resin, an acrylic resin, a fluororesin, a silicone resin, a fluorine-based polymer, a silicone-based polymer, and others.

### (Structure of Layers Below Light Emitting Element)

In the first substrate 11, the first electrode 21 included in the organic light emitting diode 211 is provided on an interlayer insulating layer 16 made of SiON. The interlayer insulating layer 16 covers a light emitting element driving unit formed on the first substrate 11.

The light emitting element driving unit includes a plurality of TFTs 15. That is, the light emitting element driving unit corresponds to a drive circuit of a pixel circuit 210. A TFT 15 includes a gate electrode 12 formed on the first substrate 11, a gate insulating film 13 formed on the first substrate 11 and the gate electrode 12, and a semiconductor layer 14 formed on the gate insulating film 13. In the semiconductor layer 14, a region located immediately above the gate electrode 12 functions as a channel region 14A, and a region located in such a manner as to sandwich the channel region 14A functions as source and drain regions 14B. Note that, in the illustrated example, the TFT 15 is a bottom-gate type; however, the following embodiments are not limited to such an example, and the TFT 15 may be a top-gate type.

An interlayer insulating layer 16 including two layers (lower interlayer insulating layer 16A and upper interlayer insulating layer 16B) is stacked on the semiconductor layer 14 by the CVD method. At this point, after the lower interlayer insulating layer 16A is stacked, contact holes 17 are formed at portions corresponding to source and drain regions 14B of the lower interlayer insulating layer 16A in such a manner as to expose the source and drain regions 14B using, for example, the photolithography technology and the etching technology, and wiring 18 made of aluminum is formed in such a manner as to fill the contact holes 17. The wiring 18 is formed by combining the vacuum deposition method and the etching method, for example. Then, the upper interlayer insulating layer 16B is stacked.

At portions of the upper interlayer insulating layer 16B where the wiring 18 is provided, contact holes 19 are formed in such a manner as to expose the wiring 18 using, for example, the photolithography technology and the etching technology. Moreover, when the first electrode 21 of the organic light emitting diode 211 is formed, the first electrode 21 is formed so as to be in contact with the wiring 18 through a contact hole 19. As described above, the first electrode 21 of the organic light emitting diode 211 is electrically connected with source and drain regions 14B of a TFT 15 (corresponds to the drain region of the drive transistor 212 in the case of the pixel circuit example illustrated in FIG. 3) via the wiring 18.

Note that, in the above example, the interlayer insulating layer 16 is made of SiON; however, the following embodiments are not limited to this example. The interlayer insulating layer 16 may be formed of various known materials that can be used as an interlayer insulating layer in a general organic EL display device. For example, as a constituent material of the interlayer insulating layer 16, a SiO₂-based material (for example, SiO₂, BPSG, PSG, BSG, AsSG, PbSG, SiON, spin on glass (SOG), low melting point glass, glass paste, or the like), a SiN-based material, and an insulating resin (for example, polyimide resin, novolac-based resin, acrylic resin, polybenzoxazole, or the like) can be used alone or in combination as appropriate. The method of forming the interlayer insulating layer 16 is also not limited to the above examples, and known methods such as the CVD method, a coating method, a sputtering method, or various printing methods may be used for forming the interlayer insulating layer 16. Furthermore, in the above example, the wiring 18 is formed by forming a film of aluminum by the vacuum vapor deposition method and the etching method and patterning the film; however, the following embodiments are not limited to such an example. The wiring 18 may be formed by forming a film of various materials used as wiring in a general organic EL display device and patterning the film by various methods.

### (Structure of Layers Above Light Emitting Element)

The opening 25 formed in the partition wall 52 of the organic light emitting diode 211 is formed in such a manner that a side wall thereof has a tapered shape inclined such that an opening area increases as the opening is closer to a lower side. Then, a protection film 31 is filled in the opening 25. That is, the protection film 31 is a layer that is provided immediately above the light emitting face of the organic light emitting diode 211 and propagates light emitted from the light emitting element upward. In addition, by forming the opening 25 of the partition wall 52 as described above, the protection film 31 in the opening 25 has a truncated cone shape with the bottom face facing upward, of which cross-sectional shape (namely, the illustrated cross-sectional shape) in the stacking direction has a substantially trapezoidal shape.

The protection film 31 is formed by forming a film of Si₁₋ₓNₓ by the vacuum vapor deposition method in such a manner as to fill the opening 25 and then planarizing the upper surface of the Si₁₋ₓNₓ film by a chemical mechanical polishing method (CMP method) or the like. However, the material of the protection film 31 is not limited to such examples, and various materials having an insulating property can be used as the material of the protection film 31. Examples of the material for forming the protection film 31 include Si₁₋ₓNₓ, ITO, IZO, TiO₂, Nb₂O₅, a bromine-containing polymer, a sulfur-containing polymer, a titanium-containing polymer, and a zirconium-containing polymer. The method of forming the protection film 31 is also not limited to such an example, and various known methods may be used as the method of forming the protection film 31.

The film thickness of the protection film 31 located above the partition wall 52 may be, for example, about 3.0 μm. However, it is not limited thereto, and various modifications may be made. A planarizing film 32 is stacked on the protection film 31 that has been planarized. The planarizing film 32 is formed by, for example, stacking SiO₂ by the CVD method by a predetermined film thickness (about 2.0 μm) and planarizing the surface thereof by the CMP method or the like.

However, the materials and film thicknesses of the protection film 31 and the planarizing film 32 are not limited to such examples, and the protection film 31 and the planarizing film 32 may be formed of various known materials used as a protection film and a planarizing film of a general organic EL display device in such a manner as to have a film thickness generally adopted in an organic EL display device.

A CF layer 33 is formed on the planarizing film 32. As described above, the display device 1 is a so-called on-chip color filter (OCCF) type display device in which the CF layer 33 is formed above the first substrate 11 on which the organic light emitting diode 211 is formed. The display device 1 is manufactured by bonding the second substrate 34 above the CF layer 33 via a sealing resin film 35 such as an epoxy resin. Note that the material of the sealing resin film 35 is not limited to such an example, and the material of the sealing resin film 35 may be selected as appropriate in consideration of high transmittance of light emitted from the organic light emitting diode 211, excellent adhesion property to the CF layer 33 located below and the second substrate 34 located above, and low reflectivity of light at an interface with the CF layer 33 located below and an interface with the second substrate 34 located above. However, the following embodiments are not limited to such an example, and the display device 1 may be a so-called counter CF type display device in which the CF layer 33 is formed on the second substrate 34, and the first substrate 11 and the second substrate 34 are bonded in such a manner that the CF layer 33 faces the organic light emitting diode 211.

The CF layer 33 is formed in such a manner that a CF of each color having a predetermined area is provided for one of organic light emitting diodes 211. The CF layer 33 can be formed, for example, by exposing and developing a resist material into a predetermined shape by the photolithography technology. Incidentally, the film thickness of the CF layer 33 is, for example, about 2 μm. However, the material, the forming method, and the film thickness of the CF layer 33 are not limited to such examples, and the CF layer 33 may be formed as appropriate to have a film thickness generally adopted in an organic EL display device by various known materials and various known methods used as a CF layer of a general organic EL display device.

In the illustrated example, the CF layer 33 is structured such that a red CF 33R, a green CF 33G, and a blue CF 33B each having a predetermined area are continuously distributed in a horizontal plane. Note that, in the following description, in a case where it is not necessary to particularly distinguish the CF 33R, the CF 33G, and the CF 33B, one or a plurality of these is also simply referred to as CF(s) 33a. One sub-pixel includes a combination of one organic light emitting diode 211 and one CF 33a.

Next, embodiments of the present disclosure will be described in detail on the basis of the drawings. Note that, in the following embodiments, description will be given focusing on a structure modified from the common structure described above. In addition, in the following embodiments, for simplification of description, the partial cross-sectional structure illustrated in FIG. 5 is illustrated in a simplified manner. For example, the layers above the protection film 31 are omitted, and the layered structure from the interlayer insulating layer 16 and below, namely, the structure including the interlayer insulating layer 16, the semiconductor layer 14, the first substrate 11, the TFTs 15, the wiring 18, and the contact holes 17 and 19 is illustrated in a simplified manner as a support substrate 101 having a flat upper surface. Furthermore, in the following description, hatching of each illustrated layer is changed from hatching of each layer in FIG. 5 for ease of viewing.

### 2. First Embodiment

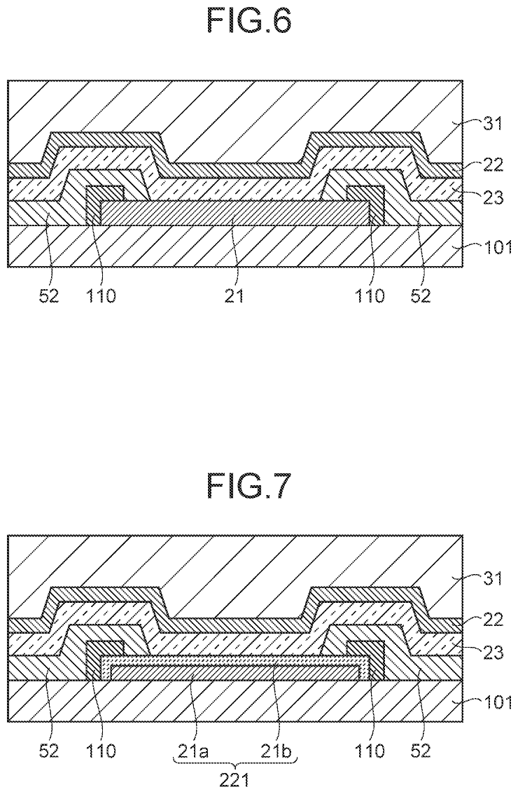

FIG. 6 is a vertical cross-sectional view illustrating a partial cross-sectional structure example of a pixel in a display device 1 according to a first embodiment. As illustrated in FIG. 6, in the present embodiment, at least a part of a peripheral portion of the first electrode 21 is covered with an antireflection film 110 provided from a side surface to the upper surface of the first electrode 21. Furthermore, the antireflection film 110 is covered in such a manner as to be buried by the partition wall 52 provided between pixels. In other words, the side surfaces and the upper surface of the antireflection film 110 are covered with the partition wall 52.

As a material of the antireflection film 110, for example, a low reflection material such as molybdenum (Mo), titanium nitride (TiN), or an anti-reflective coat (ARC) may be used. However, the material is not limited thereto, and various materials of an insulator or a conductor may be used as long as the material can reduce the intensity of light reflected, scattered, or transmitted by the antireflection film 110.

In addition, the film thickness of the antireflection film 110 provided on at least the peripheral portion of the first electrode 21 may be, for example, greater than or equal to 20 nm and, more preferably, greater than or equal to 50 nm in order to reduce light transmittance. However, the film thickness of the antireflection film 110 may be less than or equal to 1 micrometer (μm) in order to suppress a decrease in the film formation accuracy of layers from the organic layer 23 and above due to a rise of the peripheral portion of the first electrode 21.

As described above, by covering at least a part of the peripheral portion of the first electrode 21 with the antireflection film 110, even in a case where the organic layer 23 is extended over the partition wall 52, it is possible to suppress unintended light emission due to the peripheral portion of the first electrode 21 located below the partition wall 52 functioning as a reflector and to suppress light propagated in the partition wall 52 from being reflected by an electrode of an adjacent pixel and extracted as stray light. Therefore, it is possible to suppress a decrease in color purity of light extracted from each pixel. This makes it possible to suppress narrowing of the color gamut due to a decrease in color purity of each pixel.

### 3. Second Embodiment

FIG. 7 is a vertical cross-sectional view illustrating a partial cross-sectional structure example of a pixel in a display device 1 according to a second embodiment. As illustrated in FIG. 7, in the present embodiment, the first electrode 21 is replaced with a first electrode 221 in a structure similar to the cross-sectional structure described with reference to FIG. 6 in the first embodiment.

The first electrode 221 includes, for example, a lower layer electrode 21a provided on the support substrate 101 (specifically, the interlayer insulating layer 16) and an upper layer electrode 21b covering at least a part of a side surface and an upper surface of the lower layer electrode 21a.

For the lower layer electrode 21a, for example, a material similar to that of the first electrode 21 described above may be used. Meanwhile, for the upper layer electrode 21b covering the lower layer electrode 21a, for example, a transparent electrode material capable of transmitting a wavelength targeted by each pixel may be used. Examples of the transparent electrode material include indium tin oxide, zinc oxide, tin oxide, titanium oxide, and graphene.

As described above, also in a case where the first electrode 221 has a stacked structure of two or more layers and at least the uppermost layer thereof is formed of a transparent electrode, by covering at least a part of the peripheral portion of the first electrode 221 with the antireflection film 110, it is possible to suppress unintended light emission in the peripheral portion of the first electrode 221 and stray light to an adjacent pixel. Therefore, it is possible to suppress a decrease in color purity of light extracted from each pixel, thereby suppressing narrowing of the color gamut.

Note that the case where the first electrode 221 has two layers has been described as an example in FIG. 7; however, it is not limited thereto, and the first electrode may have three or more layers.

### 4. Third Embodiment

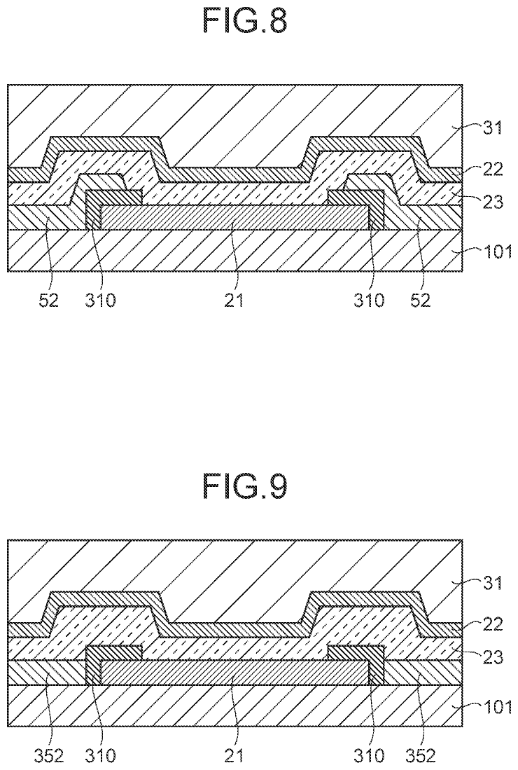

FIG. 8 is a vertical cross-sectional view illustrating a partial cross-sectional structure example of a pixel in a display device 1 according to a third embodiment. As illustrated in FIG. 8, in the present embodiment, the antireflection film 110 is replaced with an antireflection film 310 in a structure similar to the cross-sectional structure described with reference to FIG. 6 in the first embodiment.

The antireflection film 310 is provided from the side surface to the upper surface of the first electrode 21, similarly to the antireflection film 110. However, in the present embodiment, a portion of the antireflection film 310 on the upper surface of the first electrode 21 protrudes from the side surface portion of the partition wall 52 toward the center of the first electrode 21. In other words, the side surface of the antireflection film 310 on the peripheral portion of the first electrode 21 protrudes toward the center of the first electrode 21 with respect to the side surface of the partition wall 52 located on the peripheral portion of the first electrode 21.

As described above, in the case where the antireflection film 310 protrudes from the partition wall 52 on the upper surface of the first electrode 21, the region of each pixel is defined by the antireflection film 310. That is, in the present embodiment, the antireflection film 310 functions as a film that suppresses unintended light emission in the peripheral portion of the first electrode 21 and stray light to an adjacent pixel and also functions as a part of a pixel defining film. That is, in the present embodiment, the partition wall 52 and the antireflection film 310 function as a pixel defining film.

Note that, in the present embodiment, since the antireflection film 310 protrudes from the partition wall 52 which is an insulator, an insulator may be used as the material of the antireflection film 310.

Incidentally, the case where the first electrode 21 has a single layer has been described as an example in FIG. 8; however, it is not limited thereto, and the first electrode 21 may have three or more layers like in the second embodiment.

### 4.1 Modifications

FIG. 9 is a vertical cross-sectional view illustrating a modification of the partial cross-sectional structure example of the pixel in the display device 1 according to the third embodiment illustrated in FIG. 8. In the example illustrated in FIG. 9, the partition wall 52, which is provided on the antireflection film 310 provided in the peripheral portion of the first electrode 21 to an antireflection film 310 provided to a peripheral portion of a first electrode 21 of an adjacent pixel via a region between adjacent pixels in the example illustrated in FIG. 8, is replaced with a partition wall 352 provided only in a region between adjacent pixels sandwiched by antireflection films 310 of the adjacent pixels.

Also in such a structure, since the antireflection film 310 provided from the side surface to the upper surface of the first electrode 21 functions as a part of a pixel defining film, it is possible to suppress unintended light emission in the peripheral portion of the first electrode 21 and stray light to an adjacent pixel. As a result, it is possible to suppress a decrease in the color purity of light extracted from each pixel and to suppress narrowing of the color gamut.

Note that, in the present modification, an insulator may be used as a material of the antireflection film 310 in order to cause the antireflection film 310 to function as a partition wall.

Incidentally, the case where the first electrode 21 has a single layer has been described as an example in FIG. 9; however, it is not limited thereto, and the first electrode 21 may have three or more layers like in the second embodiment.

### 5. Fourth Embodiment

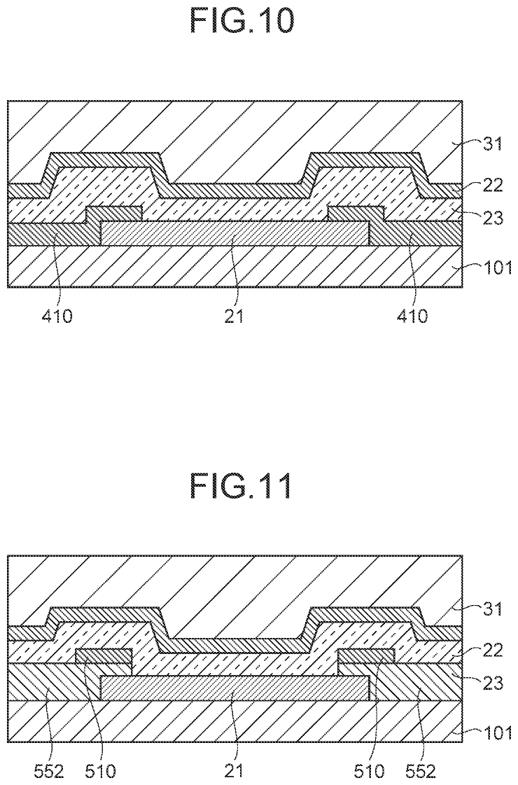

FIG. 10 is a vertical cross-sectional view illustrating a partial cross-sectional structure example of a pixel in a display device 1 according to a fourth embodiment. As illustrated in FIG. 10, in the present embodiment, the antireflection film 310 and the partition wall 352 are replaced with an antireflection film 410 in a structure similar to the cross-sectional structure described with reference to FIG. 9 in the modification of the third embodiment. That is, in the present embodiment, the partition wall 352 is omitted, and instead, the antireflection film 410 extends in such a manner as to cover a region between adjacent pixels. In other words, in the present embodiment, the partition wall 352 and the antireflection film 310 are formed of the same film (antireflection film 410).

In such a structure, the antireflection film 410 functions as a film that suppresses unintended light emission in the peripheral portion of the first electrode 21 and stray light to an adjacent pixel and also functions as a pixel defining film. That is, in the present embodiment, the partition wall 52 and the antireflection film 310 function as a pixel defining film.

Note that, in the present embodiment, an insulator may be used as a material of the antireflection film 310 in order to cause the antireflection film 310 to function as a partition wall.

Incidentally, the case where the first electrode 21 has a single layer has been described as an example in FIG. 10; however, it is not limited thereto, and the first electrode 21 may have three or more layers like in the second embodiment.

### 6. Fifth Embodiment

FIG. 11 is a vertical cross-sectional view illustrating a partial cross-sectional structure example of a pixel in a display device 1 according to a fifth embodiment. As illustrated in FIG. 11, in the present embodiment, the partition wall 52 and the antireflection film 110 are replaced with a partition wall 552 and an antireflection film 510 in a structure similar to the cross-sectional structure described with reference to FIG. 6 in the first embodiment.

The partition wall 552 has no rise at the peripheral portion of the first electrode 21 and has a substantially flat upper surface. The antireflection film 510 is provided on the upper surface of the partition wall 552 in a region covering at least a part of the peripheral portion of the first electrode 21.

As described above, also in a case where the peripheral portion of the first electrode 21 is covered with the partition wall 552 and the antireflection film 510 is provided thereon, it is possible to suppress unintended light emission in the peripheral portion of the first electrode 221 and stray light to an adjacent pixel. Therefore, it is possible to suppress a decrease in the color purity of light extracted from each pixel and to suppress narrowing of the color gamut.

Note that, in the present embodiment, since the antireflection film 510 is not in contact the first electrode 21, either an insulator or a conductor may be used as the material of the antireflection film 510.

Incidentally, the case where the first electrode 21 has a single layer has been described as an example in FIG. 11; however, it is not limited thereto, and the first electrode 21 may have three or more layers like in the second embodiment.

### 7. Sixth Embodiment

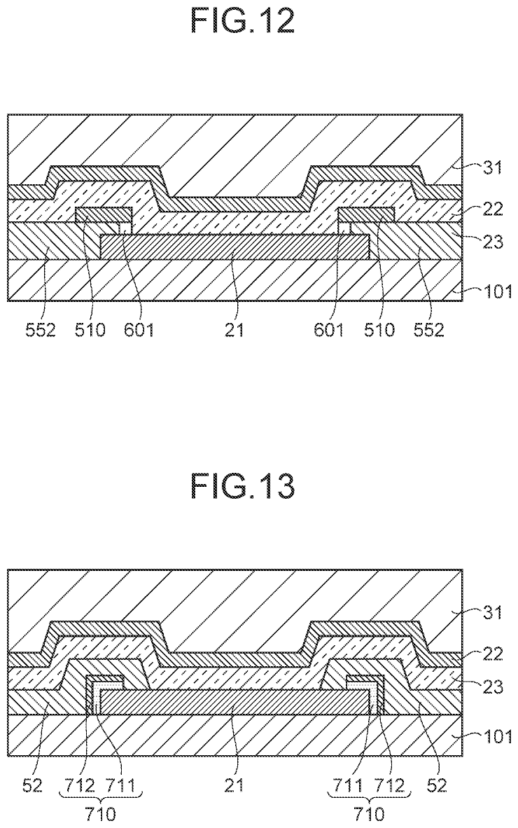

FIG. 12 is a vertical cross-sectional view illustrating a partial cross-sectional structure example of a pixel in a display device 1 according to a sixth embodiment. As illustrated in FIG. 12, in a structure similar to the cross-sectional structure described with reference to FIG. 11 in the fifth embodiment, the present embodiment has a structure in which an antireflection film 510 protrudes from an edge of the partition wall 552 on the first electrode 21 towards the center of the pixel to form an air gap 601 between the antireflection film 510 and the first electrode 21.

As described above, also in the structure in which the antireflection film 510 protrudes from the edge of the partition wall 552 to form the air gap 601 therebelow, it is possible to suppress unintended light emission in the peripheral portion of the first electrode 221 and stray light to an adjacent pixel. Therefore, it is possible to suppress a decrease in the color purity of light extracted from each pixel and to suppress narrowing of the color gamut.

Note that, in the present embodiment, as in the fifth embodiment, since the antireflection film 510 is not in contact the first electrode 21, either an insulator or a conductor may be used as the material of the antireflection film 510.

Incidentally, the case where the first electrode 21 has a single layer has been described as an example in FIG. 12; however, it is not limited thereto, and the first electrode 21 may have three or more layers like in the second embodiment.

### 8. Seventh Embodiment

FIG. 13 is a vertical cross-sectional view illustrating a partial cross-sectional structure example of a pixel in a display device 1 according to a seventh embodiment. As illustrated in FIG. 13, in the present embodiment, the antireflection film 110 is replaced with an antireflection film 710 including two or more layers in a structure similar to the cross-sectional structure described with reference to FIG. 6 in the first embodiment.

In the example illustrated in FIG. 13, the antireflection film 710 has a two-layer structure of a lower antireflection film 711 provided from the side surface to the upper surface of the first electrode 21 and an upper antireflection film 712 provided to cover a side surface and the upper surface of the lower antireflection film 711.

The lower antireflection film 711 and the upper antireflection film 712 may be made of the same material or different materials. However, it is not limited thereto, and the antireflection film 710 may have a stacked structure of three or more layers, and the materials of the layers may be the same or different.

As described above, by forming the antireflection film 710 in a stacked structure, the antireflection film 710 can function as an optical interference film that reduces the intensity of reflected light or transmitted light by utilizing the interference of light, thereby making it possible to further reduce the reflectance or transmittance of the antireflection film 710. Therefore, it is possible to further suppress unintended light emission in the peripheral portion of the first electrode 221 or stray light to an adjacent pixel. As a result, it is possible to further suppress a decrease in the color purity of light extracted from each pixel and to further suppress narrowing of the color gamut.

Incidentally, the case where the first electrode 21 has a single layer has been described as an example in FIG. 12; however, it is not limited thereto, and the first electrode 21 may have three or more layers like in the second embodiment.

### 9. Eighth Embodiment

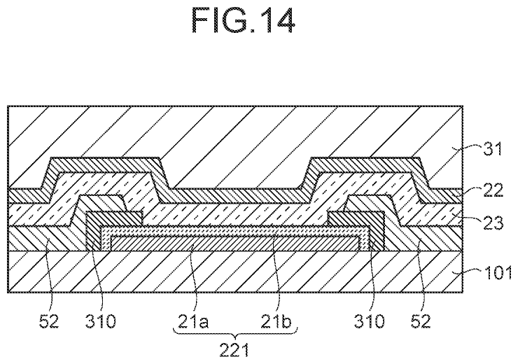

FIG. 14 is a vertical cross-sectional view illustrating a partial cross-sectional structure example of a pixel in a display device 1 according to an eighth embodiment. As illustrated in FIG. 14, the present embodiment has a structure in which the cross-sectional structure described with reference to FIG. 7 in the second embodiment and the cross-sectional structure described with reference to FIG. 8 in the third embodiment are combined.

In a case where the second embodiment is combined with another embodiment and a transparent electrode such as ITO is used for the upper layer electrode 21b of the first electrode 221, a material having a lower charge injection property than that of the upper layer electrode 21b may be used for the antireflection film 310. For example, in a case where the first electrode 221 functions as an anode of the organic light emitting diode 211, a material having a high work function may be used as the material of the antireflection film 310. Meanwhile, in a case where the first electrode 221 functions as the cathode of the organic light emitting diode 211, a material having a low work function may be used as the material of the antireflection film 310.

As described above, by using a material having a lower charge injection property than that of the upper layer electrode 21b for the antireflection film 310, it becomes possible to define light emitting regions of pixels by the antireflection film 310, and thus it is possible to retract a side end of the partition wall 52 towards the outer side of the pixel with respect to a side end of the antireflection film 310.

Note that the above-described embodiments can be combined as appropriate. For example, in FIG. 14, illustrated is the example in which the second embodiment and the third embodiment are combined; however, it is not limited thereto, and various modifications, such as a combination of the second embodiment, the fifth embodiment, and the seventh embodiment, may be made.

### 10. Ninth Embodiment

In a ninth embodiment, the planar structure of a partition wall, an antireflection film, and a first electrode according to the above-described embodiments will be described with some examples. Note that, in the following first to fourth examples, a partial planar structure example of a pixel in the display device 1 according to the first embodiment is illustrated, and in a fifth example, a partial planar structure example of a pixel in the display device 1 according to the fifth embodiment is illustrated; however, it is not limited thereto, and application to other embodiments can be made as appropriate.

### 10.1 First Example

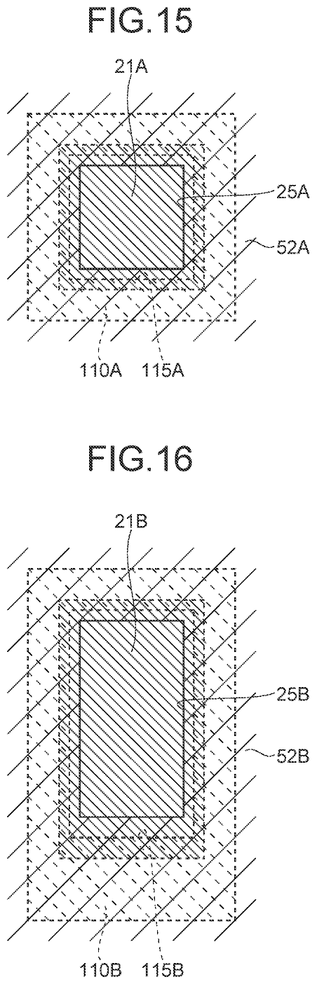

FIG. 15 is a plan view illustrating a partial planar structure example of a pixel according to a first example. As illustrated in FIG. 15, the shape of an opening 25A of a partition wall 52A, the planar shape of a first electrode 21A, the outer circumferential shape of an antireflection film 110A, and the shape of an opening 115A of the antireflection film 110A may be, for example, a rectangle such as a square or other rectangles.

In addition, the shape of the opening 25A, the planar shape of the first electrode 21A, the outer circumferential shape of the antireflection film 110A, and the shape of the opening 115A of the antireflection film 110A may be uniformly arranged such that the central axes thereof coincide with each other. However, without being limited to the above, the central axes may be non-uniformly arranged in such a manner as to be shifted in a row direction and/or a column direction.

### 10.2 Second Example

FIG. 16 is a plan view illustrating a partial planar structure example of a pixel according to a second example. As illustrated in FIG. 16, the shape of an opening 25B of a partition wall 52B, the planar shape of a first electrode 21B, the outer circumferential shape of an antireflection film 110B, and the shape of an opening 115B of the antireflection film 110B may be, for example, a stripe shape elongated in the row direction or the column direction.

In addition, the shape of the opening 25B, the planar shape of the first electrode 21B, the outer circumferential shape of the antireflection film 110B, and the shape of the opening 115B of the antireflection film 110B may be non-uniformly arranged such that the central axes thereof are shifted in the row direction and/or the column direction. However, without being limited to the above, the central axes may be uniformly arranged in such a manner as to coincide with each other.

### 10.3 Third Example

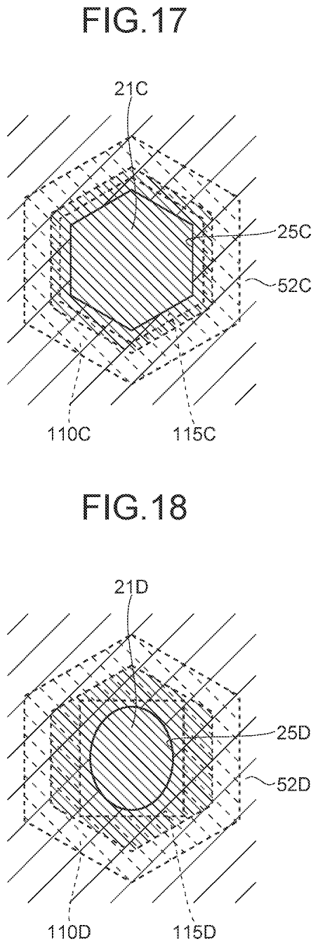

FIG. 17 is a plan view illustrating a partial planar structure example of a pixel according to a third example. Cs illustrated in FIG. 17, the shape of an opening 25C of a partition wall 52C, the planar shape of a first electrode 21C, the outer circumferential shape of an antireflection film 110C, and the shape of an opening 115C of the antireflection film 110C may be, for example, a polygon other than a square or a rectangle.

In addition, the shape of the opening 25C, the planar shape of the first electrode 21C, the outer circumferential shape of the antireflection film 110C, and the shape of the opening 115C of the antireflection film 110C may be uniformly arranged such that the central axes thereof coincide with each other. However, without being limited to the above, the central axes may be non-uniformly arranged in such a manner as to be shifted in a row direction and/or a column direction.

### 10.4 Fourth Example

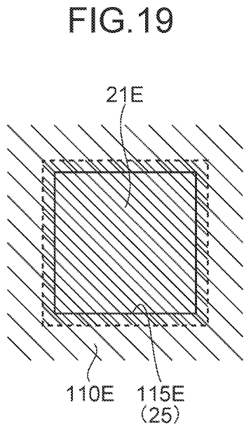

FIG. 18 is a plan view illustrating a partial planar structure example of a pixel according to a fourth example. As illustrated in FIG. 18, the shape of an opening 25D of a partition wall 52D, the planar shape of a first electrode 21D, the outer circumferential shape of an antireflection film 110D, and the shape of an opening 115D of the antireflection film 110D may be different shapes such as a rectangle, a stripe shape, a polygon, a circle, or an ellipse. However, even in this case, the planar shape of the first electrode 21D and the outer circumferential shape of the antireflection film 110D may have similar figures.

In addition, the shape of the opening 25D, the planar shape of the first electrode 21D, the outer circumferential shape of the antireflection film 110D, and the shape of the opening 115D of the antireflection film 110D may be non-uniformly arranged such that the central axes thereof are shifted in the row direction and/or the column direction. However, without being limited to the above, the central axes may be uniformly arranged in such a manner as to coincide with each other.

### 10.5 Fifth Example

FIG. 19 is a plan view illustrating a partial planar structure example of a pixel according to a fifth example. As illustrated in FIG. 19, in the structure in which the partition wall 52 is omitted, an opening 115E of an antireflection film 110E functions as an opening 25 of a pixel. In this case, the planar shape of a first electrode 21E, the outer circumferential shape of an antireflection film 110E, and the shape of an opening 115E of the antireflection film 110E may be any of the first to fourth examples described above. Note that, in FIG. 19, illustrated is a case where the planar shape of the first electrode 21E, the outer circumferential shape of the antireflection film 110E, and the shape of the opening 115E of the antireflection film 110E are similar to those of the first example.

### 11. Tenth Embodiment

In a tenth embodiment, application examples of the display devices according to the above-described embodiments will be described.

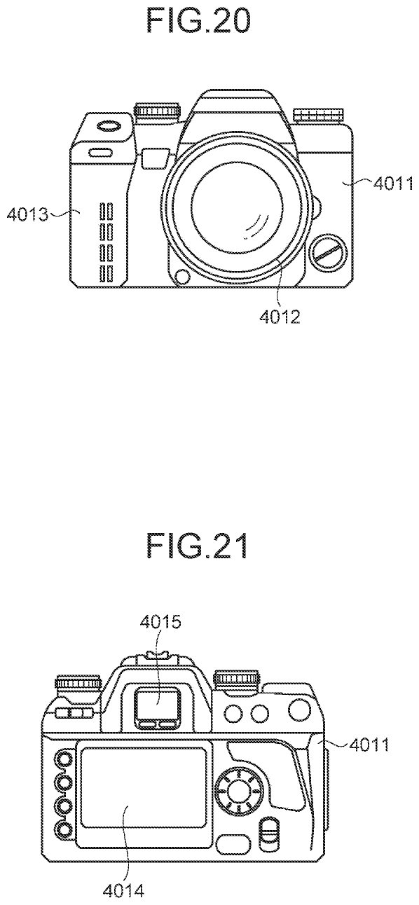

The display device according to the third embodiment described above can be applied to, for example, a digital still camera of a lens interchangeable mirrorless type. A front view of the digital still camera is illustrated in FIG. 20, and a rear view is illustrated in FIG. 21. This digital still camera of a lens interchangeable mirrorless type includes, for example, an interchangeable photographing lens unit (interchangeable lens) 4012 on the front right side of a camera main body (camera body) 4011 and a grip portion 4013 to be gripped by a photographer on the front left side. A monitor device 4014 is provided substantially at the center of the back surface of the camera main body 4011. An electronic viewfinder (eyepiece window) 4015 is provided above the monitor device 4014. By looking into the electronic viewfinder 4015, the photographer can visually recognize an optical image of a subject guided from the photographing lens unit 4012 and determine the composition. In the digital still camera of the lens interchangeable mirrorless type having such a configuration, the display device according to the third embodiment described above can be used as the electronic viewfinder 4015.

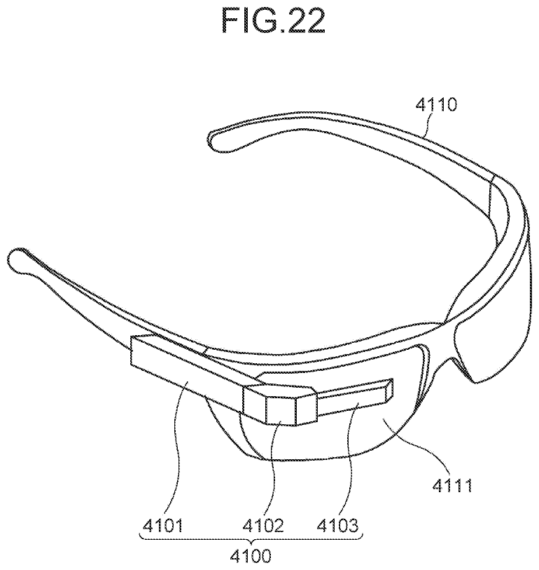

Alternatively, the display device according to the third embodiment described above can be applied to, for example, a head mounted display. As illustrated an external appearance in FIG. 22, a head-mounted display 4100 includes a transmissive head-mounted display including a main body 4101, an arm unit 4102, and a lens barrel 4103. The main body 4101 is connected with the arm unit 4102 and spectacles 4110. Specifically, an end of the main body 4101 in the longitudinal direction is attached to the arm unit 4102. In addition, one side of the side faces of the main body 4101 is connected to the spectacles 4110 via a connection member (not illustrated). Note that the main body 4101 may be directly mounted on the head of a human body. The main body 4101 incorporates a control board for controlling the operation of the head-mounted display 4100 and a display unit. The arm unit 4102 supports the lens barrel 4103 with respect to the main body 4101 by connecting the main body 4101 and the lens barrel 4103. Specifically, the arm unit 4102 fixes the lens barrel 4103 with respect to the main body 4101 by being connected to the end of the main body 4101 and an end of the lens barrel 4103. Furthermore, the arm unit 4102 incorporates a signal line for communicating data related to an image provided from the main body 4101 to the lens barrel 4103. The lens barrel 4103 projects image light provided from the main body 4101 via the arm unit 4102 toward the eyes of a user wearing the head-mounted display 4100 through lenses 4111 of the spectacles 4110. In the head-mounted display 4100 described above, the display device of the third embodiment described above can be used as a display unit incorporated in the main body 4101.

Although the embodiments of the disclosure have been described above, the technical scope of the disclosure is not limited to the above embodiments as they are, and various modifications can be made without departing from the gist of the disclosure. In addition, components of different embodiments and modifications may be combined as appropriate.

Furthermore, the effects of the embodiments described herein are merely examples and are not limiting, and other effects may be achieved.

Note that the present technology can also have the following configurations.

(1)

A semiconductor device comprising:
a plurality of pixels arrayed in a two-dimensional matrix shape; and
a partition wall disposed between the pixels, the partition wall partitioning each of the pixels,
wherein each of the pixels comprises:
a first electrode provided on a substrate;
an antireflection film provided on at least a part of a peripheral portion of the first electrode;
a light emitting layer provided on the first electrode; and
a second electrode provided on the light emitting layer.
   (2)

The semiconductor device according to (1),
wherein the antireflection film contains at least one of molybdenum or titanium nitride.
   (3)

The semiconductor device according to (1) or (2),
wherein a film thickness of the antireflection film located on the peripheral portion of the first electrode is within a range between 20 nanometers (nm) and 1 micrometer (μm).
   (4)

The semiconductor device according to any one of (1) to (3),
wherein the antireflection film is provided on at least a part of the peripheral portion from a side surface of the first electrode.
   (5)

The semiconductor device according to any one of (1) to (4),
wherein the partition wall extends over the peripheral portion of the first electrode, and
an upper surface and a side surface of the antireflection film are covered with the partition wall extending over the peripheral portion of the first electrode.
   (6)

The semiconductor device according to any one of (1) to (4),
wherein the partition wall extends over the peripheral portion of the first electrode,
a part of an upper surface of the antireflection film is covered with the partition wall extending over the peripheral portion of the first electrode, and
a side surface of the antireflection film on the peripheral portion of the first electrode protrudes towards a center of the first electrode with respect to a side surface of the partition wall located on the peripheral portion of the first electrode.
   (7)

The semiconductor device according to any one of (1) to (4),
wherein the partition wall extends over the peripheral portion of the first electrode, and
the antireflection film is provided on at least a part of the partition wall provided on the peripheral portion of the first electrode.
   (8)

The semiconductor device according to (7),
wherein a portion of the antireflection film on the peripheral portion of the first electrode protrudes towards a center of the first electrode with respect to the partition wall provided on the peripheral portion of the first electrode, and
an air gap is provided under the antireflection film protruding from the partition wall provided on the peripheral portion of the first electrode.
   (9)

The semiconductor device according to any one of (1) to (3),
wherein the antireflection film is provided on at least a part of the peripheral portion from a side surface of the first electrode, and
the partition wall is provided between the antireflection films in adjacent pixels.
   (10)

The semiconductor device according to any one of (1) to (4),
wherein the partition wall and the antireflection film are a same film.
   (11)

The semiconductor device according to any one of (1) to (10),
wherein the antireflection film has a stacked structure.
   (12)

The semiconductor device according to (11),
wherein the antireflection film is an optical interference film.
   (13)

The semiconductor device according to any one of (1) to (12),
wherein the first electrode has a stacked structure.
   (14)

The semiconductor device according to (13),
wherein the first electrode has the stacked structure,
an uppermost layer of the first electrode is a transparent electrode, and
the antireflection film is made of a material having a lower charge injection property than a charge injection property of the transparent electrode.
   (15)

The semiconductor device according to any one of (1) to (14),
wherein an opening shape of the antireflection film is similar to an opening shape of the partition wall.
   (16)

The semiconductor device according to any one of (1) to (14),
wherein an opening shape of the partition wall and an opening shape of the antireflection film are different from each other.
   (17)

The semiconductor device according to any one of (1) to (16),
wherein a central axis of an opening of the antireflection film coincides with a central axis of an opening of the partition wall.
   (18)

The semiconductor device according to any one of (1) to (16),
wherein a central axis of an opening of the antireflection film is shifted from a central axis of an opening of the partition wall.
   (19)

The semiconductor device according to any one of (1) to (18),
wherein an opening shape of the antireflection film is a rectangular shape, a stripe shape, a polygonal shape, a circular shape, or an elliptical shape.
   (20)

A display device comprising:
the semiconductor device according to any one of (1) to (19); and
a drive unit that drives the semiconductor device.

### REFERENCE SIGNS LIST

1 DISPLAY DEVICE
10 DISPLAY PANEL
11 FIRST SUBSTRATE
12 GATE ELECTRODE
13 GATE INSULATING FILM
14 SEMICONDUCTOR LAYER
14A CHANNEL REGION
14B SOURCE AND DRAIN REGION
15 TFT
16 INTERLAYER INSULATING LAYER
16A LOWER INTERLAYER INSULATING LAYER
16B UPPER INTERLAYER INSULATING LAYER
17, 19 CONTACT HOLE
18 WIRING
20 PIXEL ARRAY
21, 21A, 21B, 21C, 21D, 21E, 221 FIRST ELECTRODE
21a LOWER LAYER ELECTRODE
21b UPPER LAYER ELECTRODE
22 SECOND ELECTRODE
23 ORGANIC LAYER
24 LIGHT EMITTING UNIT
25, 25A, 25B, 25C, 25D OPENING
30 SCANNING UNIT
31 PROTECTION FILM
32 PLANARIZING FILM
33 CF LAYER
33R, 33G, 33B CF
34 SECOND SUBSTRATE
35 SEALING RESIN FILM
40 SELECTION UNIT
52, 52A, 52B, 52C, 52D, 352, 552 PARTITION WALL
101 SUPPORT SUBSTRATE
110, 110A, 110B, 110C, 110D, 110E, 310, 410, 510, 710 ANTIREFLECTION FILM
115A, 115B, 115C, 115D, 115E OPENING
210 PIXEL CIRCUIT
211 ORGANIC LIGHT EMITTING DIODE
212 DRIVE TRANSISTOR
213 SAMPLING TRANSISTOR
214 LIGHT EMISSION CONTROL TRANSISTOR
215 HOLDING CAPACITOR
216 AUXILIARY CAPACITOR
217 SWITCHING TRANSISTOR
301 WRITE SCANNING UNIT
302 SCANNING LINE
312 FIRST DRIVE LINE
311 FIRST DRIVE SCANNING UNIT
322 SECOND DRIVE LINE
321 SECOND DRIVE SCANNING UNIT
401 SIGNAL OUTPUT UNIT
402 SIGNAL LINE
601 AIR GAP
711 LOWER ANTIREFLECTION FILM
712 UPPER ANTIREFLECTION FILM

1. A semiconductor device comprising:
a plurality of pixels arrayed in a two-dimensional matrix shape; and
a partition wall disposed between the pixels, the partition wall partitioning each of the pixels,
wherein each of the pixels comprises:
a first electrode provided on a substrate;
an antireflection film provided on at least a part of a peripheral portion of the first electrode;
a light emitting layer provided on the first electrode; and
a second electrode provided on the light emitting layer.

2. The semiconductor device according to claim 1,
wherein the antireflection film contains at least one of molybdenum or titanium nitride.

3. The semiconductor device according to claim 1,
wherein a film thickness of the antireflection film located on the peripheral portion of the first electrode is within a range between 20 nanometers (nm) and 1 micrometer (μm).

4. The semiconductor device according to claim 1,
wherein the antireflection film is provided on at least a part of the peripheral portion from a side surface of the first electrode.

5. The semiconductor device according to claim 1,
wherein the partition wall extends over the peripheral portion of the first electrode, and
an upper surface and a side surface of the antireflection film are covered with the partition wall extending over the peripheral portion of the first electrode.

6. The semiconductor device according to claim 1,
wherein the partition wall extends over the peripheral portion of the first electrode,
a part of an upper surface of the antireflection film is covered with the partition wall extending over the peripheral portion of the first electrode, and
a side surface of the antireflection film on the peripheral portion of the first electrode protrudes towards a center of the first electrode with respect to a side surface of the partition wall located on the peripheral portion of the first electrode.

7. The semiconductor device according to claim 1,
wherein the partition wall extends over the peripheral portion of the first electrode, and
the antireflection film is provided on at least a part of the partition wall provided on the peripheral portion of the first electrode.

8. The semiconductor device according to claim 7,
wherein a portion of the antireflection film on the peripheral portion of the first electrode protrudes towards a center of the first electrode with respect to the partition wall provided on the peripheral portion of the first electrode, and
an air gap is provided under the antireflection film protruding from the partition wall provided on the peripheral portion of the first electrode.

9. The semiconductor device according to claim 1,
wherein the antireflection film is provided on at least a part of the peripheral portion from a side surface of the first electrode, and
the partition wall is provided between the antireflection films in adjacent pixels.

10. The semiconductor device according to claim 1,
wherein the partition wall and the antireflection film are a same film.

11. The semiconductor device according to claim 1,
wherein the antireflection film has a stacked structure.

12. The semiconductor device according to claim 11,
wherein the antireflection film is an optical interference film.

13. The semiconductor device according to claim 1,
wherein the first electrode has a stacked structure.

14. The semiconductor device according to claim 13,
wherein the first electrode has the stacked structure,
an uppermost layer of the first electrode is a transparent electrode, and
the antireflection film is made of a material having a lower charge injection property than a charge injection property of the transparent electrode.

15. The semiconductor device according to claim 1,
wherein an opening shape of the antireflection film is similar to an opening shape of the partition wall.

16. The semiconductor device according to claim 1,
wherein an opening shape of the partition wall and an opening shape of the antireflection film are different from each other.

17. The semiconductor device according to claim 1,
wherein a central axis of an opening of the antireflection film coincides with a central axis of an opening of the partition wall.

18. The semiconductor device according to claim 1,
wherein a central axis of an opening of the antireflection film is shifted from a central axis of an opening of the partition wall.

19. The semiconductor device according to claim 1,
wherein an opening shape of the antireflection film is a rectangular shape, a stripe shape, a polygonal shape, a circular shape, or an elliptical shape.

20. A display device comprising:
the semiconductor device according to claim 1; and
a drive unit that drives the semiconductor device.
